(19) United States
(12) Patent Application Publication
(10) Pub. No.: US 2007/0066047 A1
(43) Pub. Date: Mar. 22, 2007

(54) METHOD OF FORMING OPENING AND CONTACT

(76) Inventors: Jianhui Ye, Singapore (SG); Kai Hung Alex See, Singapore (SG); Tien-Cheng Lan, Singapore (SG); Meisheng Zhou, Singapore (SG)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,647

(22) Filed: Sep. 18, 2005

(51) Int. Cl. H01L 21/4763; H01L 21/302

(52) U.S. Cl. 438/620; 438/637; 438/622; 438/736; 438/638

(57) ABSTRACT

A method for forming an opening on a material layer is provided. First, a dielectric layer is formed on the material layer. Then, a metallic hard mask layer and a cap layer are sequentially formed on the dielectric layer. Thereafter, a patterned photoresist layer is formed on the cap layer. The patterned photoresist layer exposes a portion of the surface of the cap layer. After that, a first etching operation is carried out using the patterned photoresist layer as a mask to remove a portion of the cap layer and the metallic hard mask layer until the surface of the dielectric layer is exposed. Then, the photoresist layer is removed. A second etching operation is carried out using the cap layer and the metallic hard mask layer as a mask to remove a portion of the dielectric layer and form an opening.

### BACKGROUND OF THE INVENTION

1. Field of the Invention

The present invention relates to a method of forming an opening in a substrate. More particularly, the present invention relates to a method of forming an opening on a substrate such that the critical dimension of the opening can be effectively controlled and a method of forming a contact.

2. Description of the Related Art

With the rapid development of integrated circuit fabrication technologies, device miniaturization and integration is a necessary trend and an important topic in the development of the electronic industry. At present, the KrF249 mm photolithographic technique has already outgrown its applications so that the ArF193 mm photolithographic technique has to be developed to meet the demand for producing devices with a smaller line width and a higher level of integration.

In the conventional method of forming a contact opening, a semiconductor device is formed over a substrate and then a dielectric layer is formed over the substrate to cover the semiconductor device. Thereafter, a bottom anti-reflection layer is formed over the dielectric layer, followed by forming a photoresist layer over the bottom anti-reflection layer. After that, a conventional photolithographic process is used to define and form a patterned photoresist layer. Using the patterned photoresist layer as an etching mask, an etching operation is carried out to remove a portion of the bottom anti-reflection layer until the surface of the dielectric layer is exposed. Afterwards, using the patterned photoresist layer and the bottom anti-reflection layer as a mask, a portion of the dielectric layer is removed so that a contact opening that exposes the semiconductor device is formed in the dielectric layer.

In the aforementioned method of forming a contact opening, however, there are still problems need to be resolved. For example, the critical dimension (CD) of the contact opening is difficult to control. Consequently, the sidewall profile of the contact opening is difficult to control and the sidewalls often have cavities or striations, and the processing window is narrower. Ultimately, the reliability and yield of the device will be affected.

### SUMMARY OF THE INVENTION

Accordingly, at least one objective of the present invention is to provide a method of forming an opening on a substrate that can provide a larger processing window and a better control of the opening dimension and prevent the formation of striations. Consequently, the processing reliability is improved.

At least a second objective of the present invention is to provide a method of forming a contact that can provide an effective control of the critical dimension of the contact and prevent the formation of striations.

To achieve these and other advantages and in accordance with the purpose of the invention, as embodied and broadly described herein, the invention provides a method of forming an opening on a material layer. First, a dielectric layer is formed over the material layer. Then, a metallic hard mask layer and a cap layer are sequentially formed over the dielectric layer. Thereafter, a patterned photoresist layer is formed on the cap layer. The patterned photoresist layer exposes a portion of the surface of the cap layer. After that, a first etching operation is carried out using the patterned photoresist layer as a mask to remove a portion of the cap layer and the metallic hard mask layer until the surface of the dielectric layer is exposed. Then, the photoresist layer is removed. A second etching operation is carried out using the cap layer and the metallic hard mask layer as a mask to remove a portion of the dielectric layer and form an opening.

According to the embodiment of the present invention, the method further includes forming an anti-reflection layer over the cap layer. Furthermore, after removing the patterned photoresist layer, the method also includes removing the anti-reflection layer. The anti-reflection layer is a dielectric anti-reflection layer, an organic anti-reflection layer or an inorganic anti-reflection layer, for example.

According to the embodiment of the present invention, the cap layer is fabricated using silicon oxynitride, silicon oxide or a combination of them, for example. The metallic hard mask layer is fabricated using titanium, titanium nitride, tantalum, tantalum nitride, tungsten or tungsten nitride, for example. Furthermore, the metallic hard mask layer is formed, for example, by performing a chemical vapor deposition (CVD) process or a physical vapor deposition (PVD) process.

According to the embodiment of the present invention, the first etching operation and the second etching operation are anisotropic etching operations, for example. In addition, both the first etching operation and the second etching operation are carried out in the same reaction chamber.

The present invention also provides a method of forming a contact. First, a substrate having a device structure thereon is provided. Then, a dielectric layer is formed on the substrate. Thereafter, a metallic hard mask layer and a cap layer are formed in sequence on the dielectric layer. After that, a patterned photoresist layer is formed on the cap layer. The patterned photoresist layer exposes a portion of the surface of the cap layer. A first etching operation is carried out using the patterned photoresist layer as a mask to remove a portion of the cap layer and the metallic hard mask layer until the surface of the dielectric layer is exposed. Thereafter, the patterned photoresist layer is removed. Using the cap layer and the metallic hard mask layer as a mask, a second etching operation is carried out to remove a portion of the dielectric layer and form a contact opening that exposes the surface of the device structure. A conductive layer filling the contact opening is subsequently deposited to form the contact.

According to the embodiment of the present invention, the method further includes forming an anti-reflection layer on the cap layer. After removing the patterned photoresist layer, the method also includes removing the anti-reflection layer. The anti-reflection layer is a dielectric anti-reflection layer, an organic anti-reflection layer or an inorganic anti-reflection layer, for example.

According to the embodiment of the present invention, the cap layer is fabricated using silicon oxynitride, silicon oxide or a combination of them, for example. The metallic hard mask layer is fabricated using titanium, titanium nitride, tantalum, tantalum nitride, tungsten or tungsten nitride, for example. Moreover, the metallic hard mask layer is formed, for example, by performing a chemical vapor deposition (CVD) process or a physical vapor deposition (PVD) process.

According to the embodiment of the present invention, the first etching operation and the second etching operation are anisotropic etching operations, for example. In addition, both the first etching operation and the second etching operation are carried out in the same reaction chamber.

According to the embodiment of the present invention, the conductive layer is fabricated using copper, aluminum or tungsten, for example.

In the process of forming an opening in the present invention, a metallic hard mask layer and a cap layer are used as an etching mask for blocking the corrosive effect of etching gases. Therefore, the effect of the etching gases is minimized and damages to the film layer are reduced. Furthermore, the metallic hard mask layer also prevents any reduction or widening of the critical dimension of the opening so that the integrity of the opening profile can be maintained. In addition, the striations in a conventional process are also eliminated so that the reliability of the device is increased. Moreover, a larger processing window is also provided.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1G are schematic cross-sectional views showing the steps for forming a contact according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

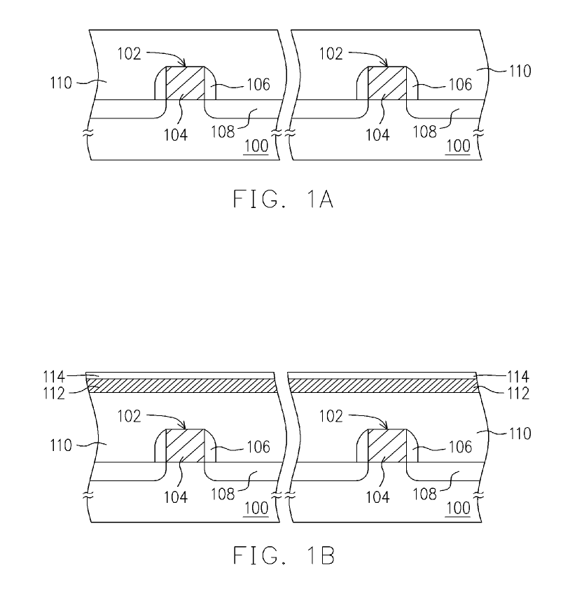

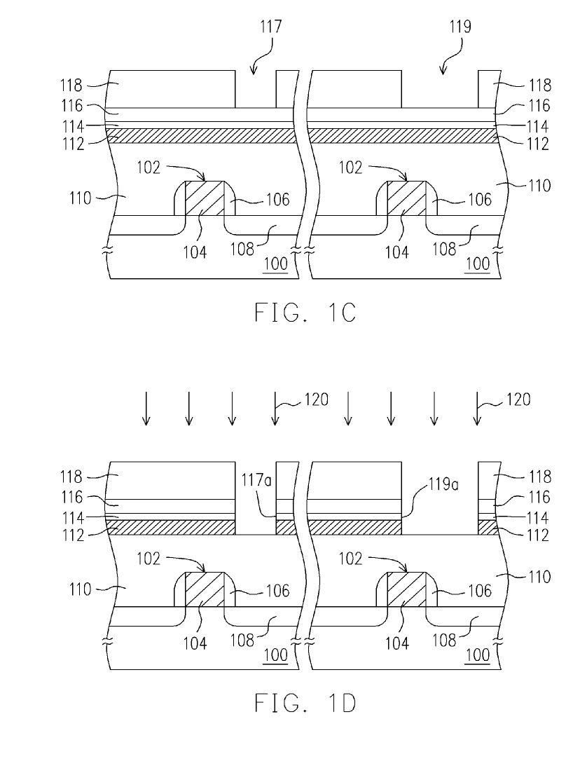

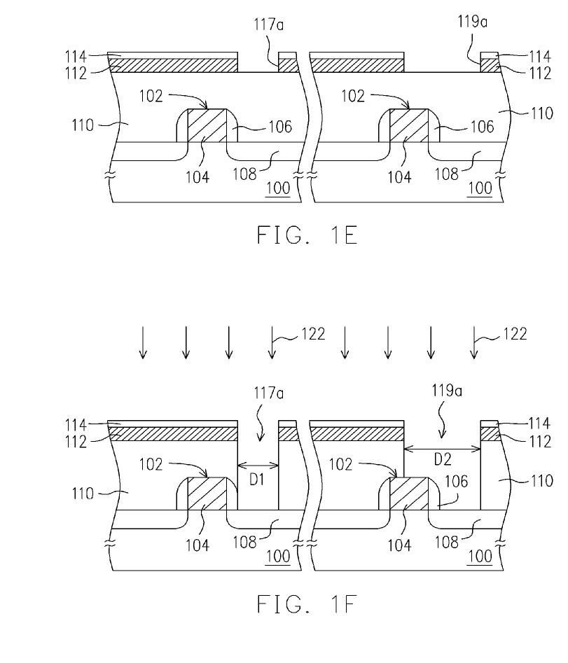

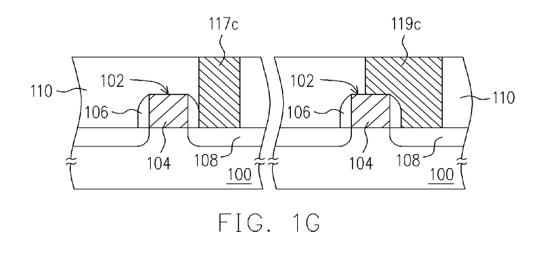

In the following, the method of forming a contact opening is used as an example to illustrate the fabrication of an opening on a substrate in the present invention. However, this should not be used to limit the scope of the present invention. In the following embodiment, a square contact opening and a shared contact opening are used as examples. The square contact opening is a contact opening that only exposes the source/drain region of a transistor and the shared contact opening is a contact opening that only exposes a portion of the gate and the source/drain region. FIGS. 1A through 1G are schematic cross-sectional views showing the steps for forming a contact according to one embodiment of the present invention.

First, as shown in FIG. 1A, a device structure is formed on a substrate 100. In the present embodiment, the device structure is a transistor 102. The substrate 100 is, for example, a silicon substrate or other type of substrate suitable for the fabrication. The transistor 102 has a gate structure 104 formed on the substrate 100 and spacers are formed on the respective sidewalls of the gate structure 104. Source/drain regions 108 are formed in the substrate 100 on the respective sides of the gate structure 104. In one embodiment, a metal silicide layer (not shown) may also form on the gate structure 104 and the source/drain regions 108 for lowering the resistivity value. The metal silicide layer can be fabricated using nickel silicide, tungsten silicide or cobalt silicide, for example. Since the material constituting various elements of the transistor 102 and the method of forming the transistor 102 are familiar to the experts in these areas, a detailed description is omitted.

Thereafter, a dielectric layer 110 is formed over the substrate 100 to cover the transistor 102. The dielectric layer 110 is, for example, a silicon oxide layer, a silicon nitride layer or other suitable dielectric material layer formed in a chemical vapor deposition (CVD) process using tetra-ethyl-ortho-silicate (TEOS) as the reactive gas. In one embodiment, an etching stop layer (not shown) is formed over the substrate 100 to serve as an etching stop before forming the dielectric layer 110. The etching stop layer prevents possible etch through that may result in a device failure. The etching stop layer is a silicon nitride layer formed by performing a chemical vapor deposition process, for example.

As shown in FIG. 1B, a metallic hard mask layer 112 is formed over the dielectric layer 110. The metallic hard mask layer 112 can be fabricated using titanium, titanium nitride, tantalum, tantalum nitride, tungsten or tungsten silicide, for example. The method of forming the metallic hard mask layer 112 includes, for example, performing a chemical vapor deposition (CVD) process or a physical vapor deposition (PVD) process. The metallic hard mask layer 112 has a thickness smaller than 1500 Å, preferably around 300 Å. Thereafter, a cap layer 114 is formed over the metallic hard mask layer 112. The cap layer 114 can be a silicon oxynitride layer, a silicon oxide layer or a silicon oxynitride/silicon oxide layer, for example. The silicon oxynitride layer has a thickness smaller than 1500 Å, but preferably between about 300 Å˜500 Å. The silicon oxide layer has a thickness smaller than 200 Å, preferably around 50 Å.

As shown in FIG. 1C, a patterned photoresist layer 118 is formed over the cap layer 114. The patterned photoresist layer 118 has opening patterns 117, 119 that exposes a portion of the surface of the cap layer 114. The opening pattern 117 is a pattern for forming a square contact opening and the opening pattern 119 is a pattern for forming a shared contact opening. In one preferred embodiment, an anti-reflection layer 116 is also formed on the cap layer 114 before forming the patterned photoresist layer 118. The anti-reflection layer 116 can be a dielectric anti-reflection layer, an organic anti-reflection layer or an inorganic anti-reflection layer formed, for example, by performing a chemical vapor deposition (CVD) process or other suitable method. The anti-reflection layer has a thickness smaller than 1000 Å, preferable around 600 Å. In particular, the anti-reflection layer 116 serves as a layer for preventing the multiple reflection and interference of light during the photolithographic process and reducing stationary wave.

As shown in FIG. 1D, an etching operation 120 is carried out using the patterned photoresist layer 118 as a mask. The etching operation 120 removes a portion of the anti-reflection layer 116, the cap layer 114 and the metallic hard mask layer 112 until the surface of the dielectric layer 110 is exposed and openings 117a, 119a are formed. The etching operation 120 is an anisotropic etching operation and the anisotropic etching operation is a plasma etching operation, for example.

As shown in FIG. 1E, the patterned photoresist layer 118 and the anti-reflection layer 116 are removed after the etching operation 120. The method of removing the patterned photoresist layer 118 and the anti-reflection layer 116 includes, for example, performing a plasma ash treatment and performing a wet etching operation thereafter.

As shown in FIG. 1F, another etching operation 122 is carried out using the cap layer 114 and the metallic hard mask layer 112 as a mask. The etching process 122 removes a portion of the dielectric layer 110 until the surface of the transistor 102 is exposed and contact openings 117b, 119b are formed. The critical dimension D1 of the contact opening 117b is about 0.15 nm and the critical dimension D2 of the contact opening 119b is about 0.30 nm, for example. Here, the contact opening 117b is a so-called square contact opening and the contact opening 119b is a so-called shared contact opening. The etching operation 122 is an anisotropic etching operation and the anisotropic etching operation is a plasma treatment, for example. In one embodiment, the etching operations 120 and 112 are carried out in the same reaction chamber.

It should be noted that the metallic hard mask layer 112 is an effective means to stop the corrosive action by the etching gases. Hence, the metallic hard mask layer 112 can protect the film layer against damages. Thus, in the etching operation 120, aside from defining the opening (the opening 117a and 119a in FIG. 1D) accurately, it also prevents the critical dimensions D1 and D2 of the contact openings 117b and 119b in the subsequent etching operation 122 from shrinking or expanding. In other words, the integrity of the opening profile is least affected. In addition, the process can prevent the formation of striations, thereby increasing processing reliability and providing a larger processing window.

Obviously, after forming the contact openings 117b and 119b, subsequent processes can be carried out to form the contact for interconnecting the devices. Therefore, as shown in FIG. 1G, conductive material is deposited into the contact openings 117b and 119b to form a conductive material layer. Then, a chemical-mechanical polishing (CMP) operation or an etching back operation is carried out to remove any redundant conductive material layer, the cap layer 114 and the metallic hard mask layer 112 until the surface of the dielectric layer 110 is exposed and the contacts 117c and 119c are formed.

Because a metallic hard mask layer and a cap layer are used as an etching mask layer in the present invention, the film layer can resist the corrosive attack by the etchant. Therefore, the critical dimension in the process of etching the contact openings can be effectively controlled. Furthermore, the method in the present invention can be applied to other process of fabricating the openings to produce openings having a better profile.

In summary, the major advantages of the present invention at least includes:

1. The method of the present invention provides a better control of the critical dimension of an opening and maintains a better integrity of the opening profile.

2. The present invention can eliminate the striations on the sidewalls of the opening and increase reliability.

3. The method in the present invention can significantly increase the process window.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of forming an opening on a material layer, comprising the steps of:
forming a dielectric layer on a material layer;
forming a metallic hard mask layer and a cap layer in sequence over the dielectric layer;
forming a patterned photoresist layer over the cap layer such that the patterned photoresist layer exposes a portion of a surface of the cap layer,
performing a first etching operation using the patterned photoresist layer as a mask to remove a portion of the cap layer and a portion of the metallic hard mask layer until a surface of the dielectric layer is exposed;
removing the patterned photoresist layer; and
after performing the first etching operation and removing the patterned photoresist layer, performing a second etching operation using the cap layer and the metallic hard mask layer as a mask to remove a portion of the dielectric layer and form an opening.

2. The method of claim 1, further includes forming an anti-reflection layer on the cap layer, and using the patterned photoresist layer as a mask to remove a portion of the anti-reflection layer in the first etching operation.

3. The method of claim 2, wherein after removing the patterned photoresist layer, further includes removing the anti-reflection layer.

4. The method of claim 2, wherein the anti-reflection layer comprises a dielectric anti-reflection layer, an organic anti-reflection layer or an inorganic anti-reflection layer.

5. The method of claim 1, wherein a material constituting the cap layer includes silicon oxynitride, silicon oxide or a combination of the above.

6. The method of claim 1, wherein a material constituting the metallic hard mask layer includes titanium, titanium nitride, tantalum, tantalum nitride, tungsten or tungsten nitride.

7. The method of claim 1, wherein the step of forming the metallic hard mask layer includes performing a chemical vapor deposition (CVD) process or performing a physical vapor deposition (PVD) process.

8. The method of claim 1, wherein the first etching operation and the second etching operation are anisotropic etching operations.

9. The method of claim 1, wherein the first etching operation and the second etching operation are carried out in the same reaction chamber.

10. A method of forming a contact, comprising the steps of:
providing a substrate having a device structure therein;
forming a dielectric layer over the substrate;
forming a metallic hard mask layer and a cap layer in sequence over the dielectric layer;
forming a patterned photoresist layer over the cap layer such that the patterned photoresist layer exposes a portion of a surface of the cap layer;
performing a first etching operation using the patterned photoresist layer as a mask to remove a portion of the cap layer and a portion of the metallic hard mask layer until a surface of the dielectric layer is exposed;
removing the patterned photoresist layer;
after performing the first etching operation and removing the patterned photoresist layer, performing a second etching operation using the cap layer and the metallic hard mask layer as a mask to remove a portion of the dielectric layer and form a contact opening that exposes a surface of the device structure; and
depositing a conductive material into the contact opening to form a contact.

11. The method of claim 10, further includes forming an anti-reflection layer on the cap layer, and using the patterned photoresist layer as a mask to remove a portion of the anti-reflection layer in the first etching operation.

12. The method of claim 11, wherein after removing the patterned photoresist layer, further includes removing the anti-reflection layer.

13. The method of claim 11, wherein the anti-reflection layer comprises a dielectric anti-reflection layer, an organic anti-reflection layer or an inorganic anti-reflection layer.

14. The method of claim 10, wherein a material constituting the cap layer includes silicon oxynitride, silicon oxide or a combination of the above.

15. The method of claim 10, wherein a material constituting the metallic hard mask layer includes titanium, titanium nitride, tantalum. tantalum nitride, tungsten or tungsten nitride.

16. The method of claim 10, wherein the step of forming the metallic hard mask layer includes performing a chemical vapor deposition (CVD) process or performing a physical vapor deposition (PVD) process.

17. The method of claim 10, wherein the first etching operation and the second etching operation are anisotropic etching operations.

18. The method of claim 10, wherein the first etching operation and the second etching operation are carried out in the same reaction chamber.

19. The method of claim 10, wherein a material constituting the conductive layer includes copper, aluminum or tungsten.
